(19) United States
(12) Patent Application Publication
(10) Pub. No.: US 2002/0151115 A1
(43) Pub. Date: Oct. 17, 2002

(54) Process for production of thin film, semiconductor thin film, semiconductor device, process for production of semiconductor thin film, and apparatus for production of semiconductor thin film

(75) Inventors: Hideharu Nakajima, Kanagawa (JP); Yoichi Negoro, Kanagawa (JP); Setsuo Usui, Kanagawa (JP)

Correspondence Address: SONNENSCHEIN NATH & ROSENTHAL, P.O. BOX 061080, WACKER DRIVE STATION, CHICAGO, IL, 60606-1080, US

(73) Assignee: Sony Corporation

(21) Appl. No.: 10/027,054

(22) Filed: Dec. 20, 2001

Related U.S. Application Data
(63) Continuation-in-part of application No. 09/946,654, filed on Sep. 5, 2001.

(30) Foreign Application Priority Data
Sep. 5, 2000 (JP) P2000-269216

(51) Int. Cl. H01L 21/00; H01L 21/84; H01L 21/76

(52) U.S. Cl. 438/149; 438/400

(57) ABSTRACT

A process for producing a thin film (particularly semiconductor thin film) which includes irradiating a raw thin film containing a volatile gas with an excimer laser beam having a pulse width of 60 ns or more, thereby removing the volatile gas from the raw thin film. The process effectively reduces the content of volatile gas such as hydrogen in thin film as in the case where degassing is performed by using an electric furnace. The degassed thin film can be recrystallized in a short time without breaking by irradiation with an excimer laser beam. Alternatively, the process consists of irradiating a thin film containing 2 atom % or more volatile gas with an excimer laser beam having a pulse width of 60 ns or more, thereby removing the volatile gas from the thin film and simultaneously crystallizing the thin film. This procedure brings about uniform nucleation, gives rise to uniform crystal grains, and prevents variation in characteristic properties.

### BACKGROUND OF THE INVENTION

The present invention relates to a process for producing thin film of polycrystalline silicon, amorphous silicon, or the like on a conductor, insulating film, insulating substrate, or the like. More particularly, the present invention relates to a process for producing such a thin film with the help of laser irradiation.

Thin-film semiconductor devices are expected to find application to liquid crystal displays of active matrix type. Their active development is under way. Thin film transistors have an active layer of polycrystalline silicon or amorphous silicon or a laminated film composed of both. Thin film transistors of polycrystalline silicon are attracting special attention because of their small size and ability to realize high-definition liquid crystal color displays of active matrix type. Forming thin film transistors as pixel switching elements on an insulating substrate such as transparent glass plate needs a new technique to modify polycrystalline silicon thin film which has been a mere electrode material or resistance material in the conventional semiconductor technology such that it has high mobility required of the transistor active layer (channel region). High mobility would make it possible to form pixel driving circuits as well as pixel transistors on the same substrate. In addition, thin film transistors with high mobility will permit considerable reduction in processing complexity and production cost and improve reliability.

On the other hand, there has been established a high-temperature process for thin film transistor devices, the process involving heat treatment at 900° C. or higher. This high-temperature process is designed to form a semiconductor thin film on a heat-resistant substrate (e.g., quartz) and then modify it by slow solid-phase epitaxy which causes crystal grains of polycrystalline silicon to grow. This process realizes high carrier mobility of about 100 cm²/V·s. However, it leads to high production cost because quarts substrates are expensive.

To cope with this situation, attempts have been made to develop a new process in place of the high temperature process using a quartz substrates. The new process employs glass substrates and achieves the desired object at a processing temperature about 600° C. or lower which glass substrates will withstand. A noteworthy process for producing thin film semiconductor devices at low temperatures is laser annealing with a laser beam, which is illustrated in FIGS. 15A to 15E.

The laser annealing process starts with growing an amorphous semiconductor thin film 102 such as amorphous silicon on a low heat-resistant substrate 101 such as glass plate, as shown in FIG. 15A. The amorphous semiconductor thin film 102 contains about 2 to 20 atom % hydrogen when it is formed by plasma-enhanced CVD, for example. In the next step, the substrate is heated for degassing in an electric furnace at 420° C. for about 2 hours, as shown in FIG. 15B. This degassing step causes the hydrogen concentration in the thin film to decrease below 2 atom %. Subsequently, the thin film is locally irradiated with a laser beam 105, as shown in FIG. 15C. Upon irradiation, the irradiated region 104 melts, and after suspension of irradiation, the irradiated region 104 cools down and changes into the recrystallized region 106, as shown in FIG. 15D. Repetition of local irradiation with laser beam 105 causes the recrystallized region 106 to extend over the substrate 101, as shown in FIG. 15E. In this way there is obtained a polycrystalline silicon film having large crystal grains. The above-mentioned Excimer laser annealing process can be applied to conducting film and insulating film as wells as semiconductor film such as Si, Ge.

Unfortunately, the above-mentioned process for forming polycrystalline silicon film reduces productivity on account of degassing by annealing in an electric furnace at 420° C. for about 2 hours in the case where the amorphous semiconductor thin film 102 is originally formed by plasma CVD. Moreover, it poses a problem that heating for degassing deforms the substrate and causes contaminants to diffuse from the glass substrate to the thin film.

One way to solve this problem was disclosed in Japanese Patent Laid-open Nos. Hei 9-186336 and Hei 9-283443. It is excimer laser annealing. According to the disclosure, hydrogen removal is accomplished by irradiation with a low-energy excimer laser beam (60 to 150 mJ/cm²). For efficient hydrogen removal, the laser beam should preferably have a high energy density; however, a laser beam with a high energy density explosively generates gas in the thin film, thereby breaking the thin film.

The conventional process for crystallization typically includes forming a thin film of amorphous silicon, irradiating the thin film with a laser beam, thereby locally heating and melting the irradiated region, and cooling the thin film for recrystallization, with laser irradiation suspended. This process which includes a repetition of melting and cooling gives a polycrystalline semiconductor film composed of large crystal grains, which realizes high electron mobility owing to reduced carrier scattering. Thus, the polycrystalline semiconductor film permits high-performance thin-film transistors to be formed therein. With a large number of thin-film transistors, it is possible to form high-performance integrated circuits. Needless to say, the excimer laser annealing method (ELA method) can be applied to conductor film and insulator film as well as semiconductor film.

Unfortunately, the disadvantage of crystallization by the above-mentioned method is that it is difficult to provide completely uniform energy so long as surface emitting semiconductor laser is used. Moreover, it is also difficult to form amorphous silicon (a-Si) film with completely uniform thickness and film quality such as crystallizability. Therefore, it is practically impossible to generate crystals with uniform size within the entire region of irradiated surface. Uniform crystallization over the entire surface needs a new technology capable of more uniform, stabler nucleation than the conventional laser annealing method.

### SUMMARY OF THE INVENTION

It is an object of the present invention to provide a process for producing thin film (particularly semiconductor thin film) which decreases the hydrogen content in thin film as in the conventional process that employs an electric furnace, without adverse effect on productivity and possibility of film breakage. It is another object of the present invention to provide a process for producing thin film (particularly semiconductor thin film) which is characterized by its ability to perform uniform, stable nucleation for polycrystalline film with even crystal grains regardless of fluctuation in film thickness and film quality.

It is still another object of the present invention to provide a semiconductor thin film and a semiconductor device produced by the process. It is yet another object of the present invention to provide a process and apparatus for efficient production of high-quality semiconductor thin film.

To achieve the above object, according to an aspect of the present invention, there is provided a process for producing a degassed thin film which includes irradiating a raw thin film containing a volatile gas with an excimer laser beam having a pulse width of 60 ns or more, thereby removing the volatile gas from the raw thin film. According to a preferred embodiment of the present invention, the raw thin film is one which contains at least 2 atom % volatile gas. Particularly, it is a semiconductor thin film such as amorphous silicon film and polycrystalline silicon film, which has a thickness of 1 nm or more. In addition, the raw thin film is one which is formed by any one or more of plasma CVD, low-pressure CVD, atmospheric CVD, catalytic CVD, photo CVD, and laser CVD. Irradiation with excimer laser may be by one beam or a combination of two or more beams of different kinds. This means that the two or more laser beams may differ in intensity. For example, irradiation may be a combination of irradiation with an intensity of 300 mJ/cm² or lower (repeated several times) and irradiation with an intensity of 300 mJ/cm² or higher (repeated several times). The pulse width should be from 60 ns to 300 ns, preferably from 100 ns to 250 ns, more preferably from 120 ns to 230 ns.

According to another aspect of the present invention, there is provided a process for producing a thin film which includes irradiating a raw thin film containing a volatile gas with an excimer laser beam such that at least one region in the thickness direction of the raw thin film remains at a temperature lower than the recrystallizing temperature of the material of the raw thin film, thereby removing the volatile gas from the raw thin film. Irradiation with an excimer laser beam should preferably be performed in such a way that the temperature in the vicinity of the surface of the raw thin film is lower than the recrystallizing temperature of the material of the raw thin film. In other words, if the material of the thin film is amorphous silicon or polycrystalline silicon, the temperature in the vicinity of the raw thin film should be in the range of 800° C. to 1100° C. The material of the raw thin film may be either amorphous silicon or polycrystalline silicon. The temperature in the vicinity of the surface of the raw thin film may be higher than the recrystallizing temperature of the material of the raw thin film and the temperature in the portion at a specific depth or more from the surface of the raw thin film may be in the range of 800° C. to 1100° C. The specific depth is 10 nm, preferably 5 nm, and more preferably 3 nm.

The present invention is directed also to a semiconductor thin film which contains less volatile gas than its raw thin film as the result of irradiation with an excimer laser beam having a pulse width of 60 ns or more. The present invention is directed also to a semiconductor device which has the semiconductor thin film formed on a substrate. The substrate should preferably be a glass substrate.

According to another aspect of the present invention, there is provided a process for producing a semiconductor thin film which includes forming a raw semiconductor thin film on a substrate, irradiating the raw semiconductor thin film with an excimer laser beam having a pulse width of 60 ns or more, thereby removing a volatile gas from the raw semiconductor thin film, and subsequently irradiating the degassed semiconductor thin film with an energy beam, thereby crystallizing the degassed semiconductor thin film. The energy beam should preferably be an excimer laser beam. The process may be modified such that irradiation with an excimer laser beam is followed by irradiation with an energy beam without being opened to atmospheric air.

The present invention is directed also to an apparatus for producing a semiconductor thin film which includes a first treatment chamber in which a raw semiconductor thin film is formed on a substrate and a second treatment chamber adjacent to the first treatment chamber in which the substrate is irradiated with an excimer laser beam having a pulse width of 60 ns or more for removal of volatile gas from the raw semiconductor thin film formed on the substrate. The apparatus should preferably be operated such that the semiconductor thin film is crystallized by irradiation with an energy beam.

The advantage of using the excimer laser beam in the present invention is that degassing can be accomplished in an extremely short time compared with degassing in an electric furnace. Irradiation with an excimer laser beam having a pulse width (duration) of 60 ns or more injects a less amount of energy per unit time into the thin film than irradiation with a conventional excimer laser beam having a pulse width of about 50 ns or less. The advantage of this difference is that the entire thin film is heated uniformly because heat due to energy absorption dissipates in the thickness direction of the thin film before the surface temperature rises excessively. Uniform heating leads to uniform degassing or removal of volatile gas such as hydrogen from the thin film.

The present invention is characterized in performing irradiation with an excimer laser such that the thin film is kept at a temperature lower than the recrystallizing temperature of the material of the thin film. The advantage of irradiation in such a way is that the laser beam has its energy converted into heat upon absorption in the vicinity of the surface of the thin film but the thus generated heat does not bring about substantial melting in the vicinity of the surface of the thin film and in the film and hence does not bring about recrystallization because the temperature in at least one region of the thin film remains below the recrystallizing temperature of the material of the thin film. The consequence is efficient removal of volatile gas such as hydrogen from the thin film. During irradiation, the temperature at the outermost surface of the thin film may exceed the crystallizing temperature because degassing readily takes place there; however, the temperature at the part beyond a prescribed depth from the surface should remain under the recrystallizing temperature of the material of the thin film. The prescribed depth is 10 nm, preferably 5 nm, and more preferably 3 nm. In a preferred embodiment, irradiation should be performed such that the temperature of the thin film including the surface thereof is lower than the recrystallizing temperature of the material of the thin film.

According to the present invention, the process and apparatus for producing a semiconductor thin film are designed to irradiate a raw semiconductor thin film with an excimer laser beam, thereby removing a volatile gas from the raw semiconductor thin film, and then irradiate the degassed semiconductor thin film with an energy beam, thereby crystallizing the semiconductor thin film. The process and apparatus may be applied to the production of high-performance devices with a high mobility through degassing and crystallization that take place when the channel parts of thin-film transistors are irradiated with beams.

The above-mentioned process is based on a fundamental idea of removing any volatile gas from a thin film and subsequently subjecting the thin film to crystallization. This idea has been expanded to another idea of performing degassing and crystallization simultaneously, on which the second aspect of the present invention is based. The second aspect of the present invention is intended to tackle the problem involved in the conventional technology by means of a new process which consists of forming a thin film (particularly semiconductor thin film) in such a way as to purposely add hydrogen thereto and irradiating it with an energy beam (particularly an excimer laser beam having a long duration time per pulse), so that it undergoes crystallization. Upon irradiation with an excimer laser, the thin film containing a volatile gas undergoes a change such that at least its surface layer melts and the volatile gas contained therein releases itself forming microbubbles. These microbubbles in the molten film take away evaporation heat therefrom, thereby cooling it locally. The cooled part of the thin film which is below the crystallization point permits crystalline nuclei to occur therein selectively. This nucleation takes place uniformly because the gas contained in the thin film has a small mass and hence has a long mean free path (which means a uniform gas distribution in the thin film). This improved uniformity is an advantage over the conventional method of simple laser annealing.

The above-mentioned idea has led to the second aspect of the present invention which is directed to a process for producing a thin film which includes irradiating a thin film containing no less than 2 atom % of volatile gas with an excimer laser beam having a pulse width no shorter than 60 ns, thereby simultaneously removing the volatile gas from the thin film and crystallizing at least part of the thin film. The second aspect of the present invention is also directed to a semiconductor thin film which is characterized in having the content of volatile gas therein reduced from 2 atom % or more and also having at least part thereof crystallized as the result of irradiation with excimer laser beams having a pulse width no shorter than 60 ns. The second aspect of the present invention is also directed to a process for producing a semiconductor thin film which includes forming on a substrate a semiconductor thin film containing no less than 2 atom % of volatile gas and irradiating the semiconductor thin film with an excimer laser beam having a pulse width no shorter than 60 ns, thereby simultaneously removing volatile gas from the semiconductor thin film and crystallizing at least part of the semiconductor thin film.

According to the present invention, the above-mentioned process for producing a thin film (particularly a semiconductor thin film) offers the following advantages. Upon irradiation with an excimer beam, a semiconductor thin film containing a volatile gas absorbs the laser energy in its surface layer (approximately 10 nm thick), so that the surface layer melts, permitting the volatile gas to vaporize instantaneously and release itself uniformly from the entire surface of the thin film. At the same time, heat conducts from the surface layer to that part of the thin film which is close to the interface of the substrate. The thus heated part of the thin film begins to melt. This melting causes the volatile gas to release itself from the film and to gather together, forming microbubbles at certain intervals. These microbubbles in the molten thin film take away evaporation heat therefrom, causing the molten part of the thin film to cool locally, with the result that nucleation takes place earlier than the other part. In this way it is possible to form nuclei more uniformly than the conventional method that employs excimer laser annealing for random generation of microbubbles and nuclei in the interface between the substrate and the thin film, because the volatile gas can be readily and uniformly incorporated into the thin film during its production. As mentioned above, the present invention realizes uniform nucleation in the film-substrate interface at the time of excimer laser annealing and hence yields a polysilicon thin film with uniform grain size through crystallization by excimer laser annealing. The thus obtained thin film can be used for thin film transistors (TFT) with a minimum of variation in their characteristic properties. Such uniform TFTs are desirable for high-performance TFT devices because the device performance depends on the worst among TFTs with varied characteristic properties.

The above-mentioned process is characterized in that the excimer laser beam has an intensity of irradiation energy higher than the threshold value of energy for the thin film to crystallize. The excimer laser used in the process is XeCl excimer laser, for instance The excimer laser should preferably have an intensity of irradiation energy of 250 to 450 mJ/cm². The thin film containing a volatile gas is a semiconductor thin film, for instance. The semiconductor thin film contains at least partly amorphous silicon film. The thin film is one which is formed by any one or more of plasma CVD, low-pressure CVD, atmospheric CVD, catalytic CVD, photo CVD, and laser CVD. The thin film has a thickness of 10 to 100 nm. The thin film contains at least one kind of atoms selected from hydrogen atoms, fluorine atoms, chlorine atoms, helium atoms, argon atoms, neon atoms, krypton atoms, and xenon atoms, of which the volatile gas is composed.

The above-mentioned degassing and crystallization should preferably be carried out such that the thin film is irradiated with the excimer laser beam more than once. The irradiation with excimer laser beam more than once may be carried out with varied intensities of irradiation energy. The irradiation with excimer laser beam more than once may be carried out such that the position of irradiation is shifted each time of irradiation. Irradiation with excimer laser beam may be carried out more than once in such a way that the position of irradiation is shifted each time of irradiation so that the region of preceding irradiation partly overlaps with the region of succeeding irradiation. Alternatively, irradiation with excimer laser beam is carried out more than once in such a way that the position of irradiation is shifted each time of irradiation so that the region of preceding irradiation adjoins the region of succeeding irradiation. Moreover, at least part of the region for irradiation with the excimer laser is irradiated with spatially modulated excimer laser beam in such a way that the position of irradiation is shifted each time of irradiation. In this case, the modulation is accomplished in such a way that the intensity of irradiation energy decreases as the excimer laser beam advances.

### BRIEF DESCRIPTION OF THE DRAWINGS

FIG. 1 is a schematic diagram showing one example of the degassing apparatus used for production of thin film in the first embodiment;

FIGS. 2A to 2E are sectional views illustrating the steps of producing thin film in the first embodiment, FIG. 2A shows a step of forming an amorphous semiconductor thin film, FIG. 2B shows a step of irradiation with a laser beam for degassing, FIG. 2C shows a continued step of irradiation with a laser beam, FIG. 2D shows a step of irradiation with a laser beam for recrystallization, and FIG. 2E shows a continued step of irradiation with a laser beam;

FIG. 3 is a graph showing how the conventional excimer laser beam affects the temperature distribution in the thickness direction;

FIG. 4 is a graph showing how the excimer laser beam in the present invention affects the temperature distribution in the thickness direction;

FIG. 5 is a schematic perspective view showing the display unit of active matrix type which has thin-film semiconductor devices produced according to the process of the present invention;

FIGS. 6A to 6E are sectional views illustrating the steps of producing thin film in the third embodiment, FIG. 6A shows a step of forming an amorphous semiconductor thin film, FIG. 6B shows a first step of irradiation with a laser beam for degassing, FIG. 6C shows a continued step of irradiation with a laser beam, FIG. 6D shows a second step of irradiation with a laser beam for degassing, and FIG. 6E shows a continued step of irradiation with a laser beam;

FIGS. 7A and 7B are sectional views illustrating the steps of producing thin film in the third embodiment, FIG. 7A shows a step of irradiation with a laser beam for recrystallizing, and FIG. 7B shows a continued step of irradiation with a laser beam;

FIG. 8 is a graph showing the relation between the number of shots of irradiation with an excimer laser beam and the hydrogen content in an amorphous silicon film after irradiation with an excimer laser beam;

FIG. 9 is a schematic diagram showing the construction of the apparatus for producing a semiconductor thin film in the fourth embodiment of the present invention;

FIGS. 10A to 10C are sectional views illustrating the apparatus and process for producing a semiconductor thin film in the fourth embodiment of the present invention, FIG. 10A shows the step for CVD, FIG. 10B shows the step of transferring the substrate, and FIG. 10C shows the step of degassing;

FIGS. 11A and 11B are sectional views illustrating the apparatus and process for producing a semiconductor thin film in the fourth embodiment of the present invention, FIG. 11A shows the step of crystallization, and FIG. 11B shows the step of discharging the substrate;

FIG. 12 is a schematic diagram showing the construction of the apparatus for producing a semiconductor thin film in the fifth embodiment of the present invention;

FIG. 13 is a schematic diagram showing the construction of the apparatus for producing a semiconductor thin film in the sixth embodiment of the present invention;

FIG. 14 is a schematic diagram showing the construction of the apparatus for producing a semiconductor thin film in the seventh embodiment of the present invention;

FIGS. 15A to 15E are sectional views illustrating the steps of producing thin film in the conventional process, FIG. 15A shows a step of forming an amorphous semiconductor thin film, FIG. 15B shows a step of degassing in an electric furnace, FIG. 15C shows a step of irradiation with a laser beam, FIG. 15D shows a step of recrystallization, and FIG. 15E shows a continued step of recrystallization;

FIG. 16 is an electron micrograph (×20000) of a semiconductor thin film produced according to the present invention; and

FIG. 17 is an electron micrograph (×50000) of a semiconductor thin film produced according to the present invention.

### DETAILED DESCRIPTION OF THE PREFERRED EMBODIMENTS

The invention will be described in more detail with reference to its embodiments. According to the present invention, the process for producing a thin film includes irradiating a raw thin film containing a volatile gas with an excimer laser beam having a pulse width of 60 ns or more, thereby removing the volatile gas from the raw thin film and further undergoing the degassing and crystallization simultaneously.

### FIRST EMBODIMENT

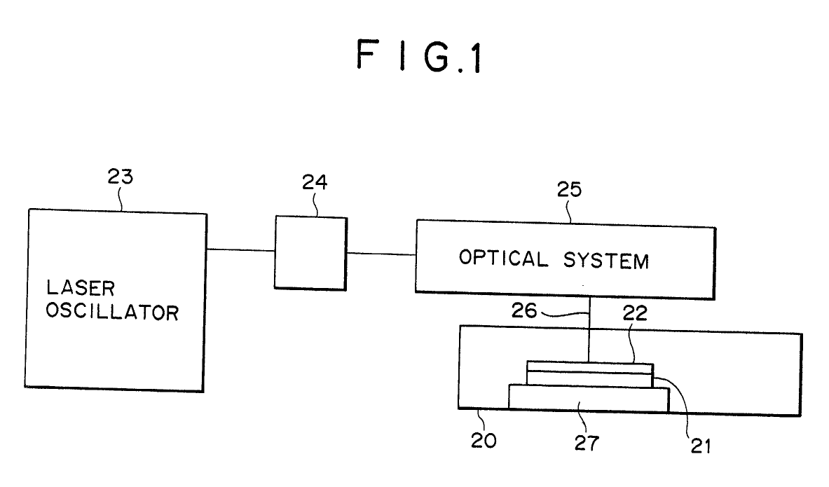

This embodiment demonstrates production of a thin film by use of a laser degassing apparatus as shown in FIG. 1. The laser degassing apparatus is designed to reduce the content of volatile gas such as hydrogen in a semiconductor thin film 22 formed on an insulating substrate 21 with low heat resistance such as glass substrate. It has a chamber 20 in which is mounted an insulating substrate 21 on which a semiconductor thin film 22 has been formed. In addition, the laser degassing apparatus has a laser oscillator 23, an attenuator 24, and an optical system 25 including a homogenizer. The chamber 20 is provided with a stage 27 movable in the X-Y directions. On the stage 27 is mounted an insulating substrate 21 on which a semiconductor thin film 22 has been formed. The laser oscillator 23 contains an excimer laser light source. It intermittently emits a laser beam 26 having a pulse width of 60 ns or more. The optical system 25, which contains a homogenizer, receives through the attenuator 24 the laser beam emitted from the laser oscillator 23. The optical system reshapes the laser beam so that it has a rectangular cross section, each side larger than 10 mm, and it directs the laser beam to the semiconductor thin film 22. The attenuator 24 controls the energy of the laser beam emitted from the laser oscillator 23. The optical system reshapes the laser beam so that it has a rectangular cross section and controls the laser beam so that energy is uniformly distributed in the rectangular cross section. The chamber 20 is filled with an inert atmosphere such as nitrogen gas. At the time of irradiation with the laser beam 26, the stage is moved in such a way that one edge of the rectangular cross section of the laser beam overlaps with one edge of the rectangular cross section of the next laser beam. In this way the semiconductor thin film 22 is irradiated with laser beams intermittently.

The laser degassing apparatus shown in FIG. 1 is designed to remove volatile gas from the semiconductor thin film 22 covering the main surface of the insulating substrate 21 while the substrate 21 is placed in the chamber 20 of the apparatus. The removal of volatile gas is necessary because the semiconductor thin film 22 contains hydrogen as volatile gas if it is an amorphous silicon film formed from silane gas by plasma CVD or the semiconductor film 22 contains part of atmosphere gas or target atoms if it is formed by sputtering. According to this embodiment, volatile gas such as hydrogen is removed by irradiation with a laser beam. In this embodiment, the laser beam is an excimer laser beam having a pulse width of 60 ns or more which is produced by the laser oscillator 23. The excimer laser beam used in the present invention differs from the conventional one used for crystallization which has a pulse width of 50 ns or below. Irradiation of thin film with the conventional excimer laser beam for removal of volatile gas such as hydrogen causes volatile gas to explosively expand, thereby breaking the thin film. By contrast, the excimer laser beam used in the present invention which has a pulse width of 60 ns or more does not excessively raise the surface temperature of the semiconductor thin film 22, and it accomplishes degassing without breaking the thin film.

The laser oscillator 23, which emits an excimer laser beam having a pulse width of 60 ns or more, may employ any excimer laser so long as it removes volatile gas such as hydrogen without excessively raising the surface temperature of the semiconductor thin film 22. It uses any one or more excited species selected from Ar₂, Kr₂, Xe₂, F₂, Cl₂, KrF, KrCl, XeCl, XeF, XeBr, XeI, ArF, ArCl, HgCl, HgBr, HgI, HgCd, CdI, CdBr, ZnI, NaXe, XeTl, ArO, KrO, XeO, KrS, XeS, XeSe, Mg₂, and Hg₂.

The excimer laser beam does not excessively heat the surface of the thin film so long as it has a pulse width of 60 ns or more. The pulse width should range from 60 ns to 300 ns, preferably from 100 ns to 250 ns, more preferably from 120ns to 230 ns. With a pulse width exceeding the upper limit of 300 ns, the excimer laser beam has an excessively low energy density per unit area and hence is incapable of effective degassing.

The present invention requires that the excimer laser should have a pulse width of 60 ns or more. This condition is necessary for the excimer laser to perform degassing while keeping the thin film below the recrystallizing temperature of its material at the time of irradiation. Thus the thin film is degassed efficiently without crystallization. In particular, smooth degassing can be accomplished without recrystallization in the vicinity of the surface of the thin film if irradiation is performed in such a way that the vicinity of the surface of the thin film or a region in the thin film at a certain depth from the surface of the thin film remains below the recrystallization temperature of the material of the thin film. In the case where the thin film is amorphous silicon film or polycrystalline silicon film, irradiation with an excimer laser beam should be carried out such that the temperature of the thin film remains at 800° C. to 1100° C. because silicon crystallizes at about 114° C.

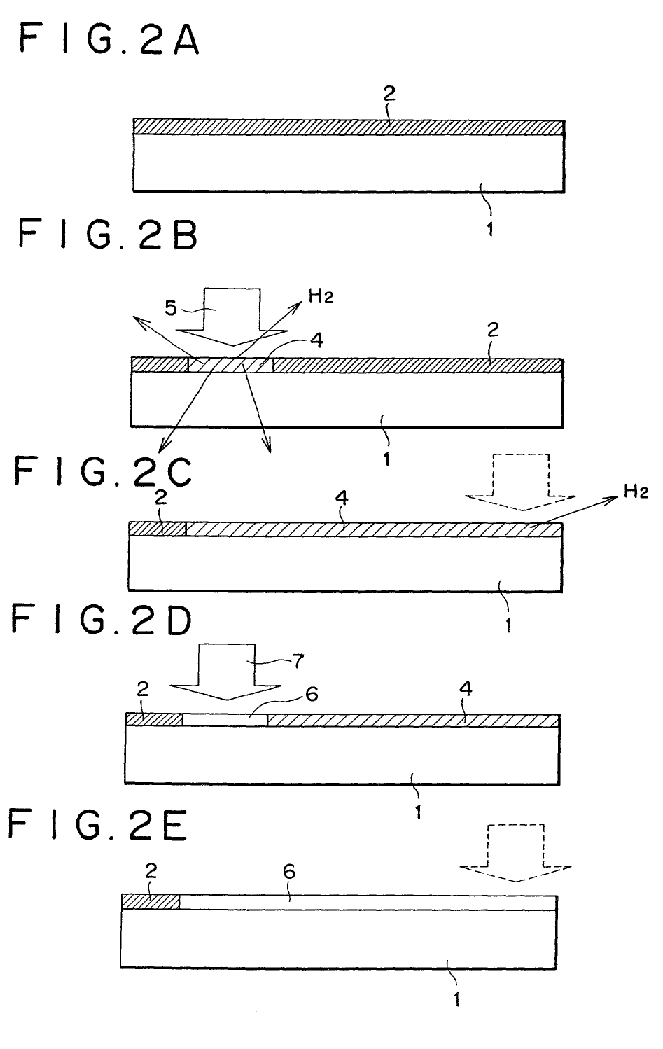

This embodiment is carried out to produce a thin film by the process explained below with reference to FIGS. 2A to 2E. The process starts with forming an amorphous semiconductor thin film 2 by plasma-enhanced CVD or the like on an insulating substrate 1 of glass, quartz, or sapphire, as shown in FIG. 2A. The insulating substrate 1 may be a colorless glass plate with low heat resistance because this embodiment employs excimer laser. The amorphous semiconductor thin film 2 may be an amorphous silicon film. It may contain 10 atom % hydrogen or less if it is formed by plasma-enhanced CVD. The thickness of the amorphous semiconductor thin film 2 is about 50 nm in this embodiment but it may be adequately adjusted according to the characteristic properties required of the device to be produced. The semiconductor thin film 2 may contain hydrogen as a major volatile gas. The volatile gas may additionally include helium, argon, neon, krypton, xenon, and the like. It may also include gas originating from the atmosphere used for CVD or atoms originating from the target used for sputtering. The amount of volatile gas in the thin film may be 2 atom % or more. The above-mentioned plasma-enhanced CVD may give a hydrogenated thin film containing 10 atom % hydrogen or less.

The insulating substrate 1, on which the amorphous semiconductor thin film 2 has been formed, is irradiated with an excimer laser beam 5 as shown in FIG. 2B so that an irradiated region 4 is formed in part of the amorphous semiconductor thin film 2. The excimer laser beam 5 should have a pulse width of 60 ns or more, preferably from 60 ns to 300 ns, more preferably from 100 ns to 250 ns, and most desirably from 120 ns to 230 ns. Irradiation with the excimer laser beam may be carried out once with an energy intensity of 350 mJ/cm² or repeatedly, for example 50 times, with an energy intensity of 300 mJ/cm². An excimer laser beam with a pulse width of 60 ns or more is intense enough to remove hydrogen etc. from the amorphous semiconductor thin film 2. Consequently, the content of volatile gas in the irradiated region 4 certainly decreases even in the case where the amorphous semiconductor thin film 2 is a hydrogenated thin film containing 10 atom % hydrogen or less. An amorphous silicon film should preferably contain 8 atom % hydrogen or less so that it will not suffer ablation as it releases hydrogen. If the amorphous silicon film needs polycrystallization, the hydrogen content therein should be 2 atom % to 5 atom %.

Then, the irradiated region 4 in the amorphous semiconductor thin film 2 is expanded until it covers a large portion of the surface of the insulating film 1, as shown in FIG. 2C. This step may be carried out by intermittent irradiation in sequence during which the stage in the chamber is moved such that one edge of the rectangular cross section of the laser beam overlaps with one edge of the rectangular cross section of the next laser beam. Such irradiation may be carried out not only in such area-sequence but also in line-sequence. It is possible to scan the laser beam instead of moving the stage, or it is possible to move both the stage and the laser beam. In the irradiated region 4, the hydrogen content in the thin film decreases. Thus, after irradiation, the amorphous semiconductor thin film 2 may contain 2 at atom % hydrogen or less.

The degassing step is followed by annealing with an excimer laser beam 7 as shown in FIG. 2D. This annealing promotes recrystallization in the amorphous semiconductor thin film 2. The excimer laser beam for this purpose should have an intensity higher than the crystallizing energy of the material of the amorphous semiconductor thin film 2. Irradiation is carried out once or several times with an excimer laser beam having an energy of 500 mJ/cm². Irradiation in this manner recrystallizes the amorphous semiconductor thin film 2. With crystal grains enlarged by recrystallization, it becomes the recrystallized region 6 which consist of the polycrystalline semiconductor thin film.

This step may be carried out by intermittent irradiation during which the stage in the chamber is moved such that one edge of the rectangular cross section of the laser beam overlaps with one edge of the rectangular cross section of the next laser beam, as shown in FIG. 2E. It is possible to scan the laser beam instead of moving the stage, or it is possible to move both the stage and the laser beam. The step of forming the recrystallized region 6 proceeds without the semiconductor thin film 2 exploding because of its reduced hydrogen content after conversion into the irradiated region 4.

The process in this embodiment involves irradiation with the laser beam 5 for hydrogen removal and irradiation with the laser beam 7 for recrystallization. These two steps may be carried out in separate apparatus or in the same chamber consecutively, with the energy level changed. The substrate may be transferred through adjoining chambers without being exposed to atmospheric air.

The foregoing is a step-by-step illustration of the embodiment. Now, the following shows how the temperature difference in a semiconductor thin film varies depending on irradiation with the excimer laser of the present invention and irradiation with the conventional excimer laser.

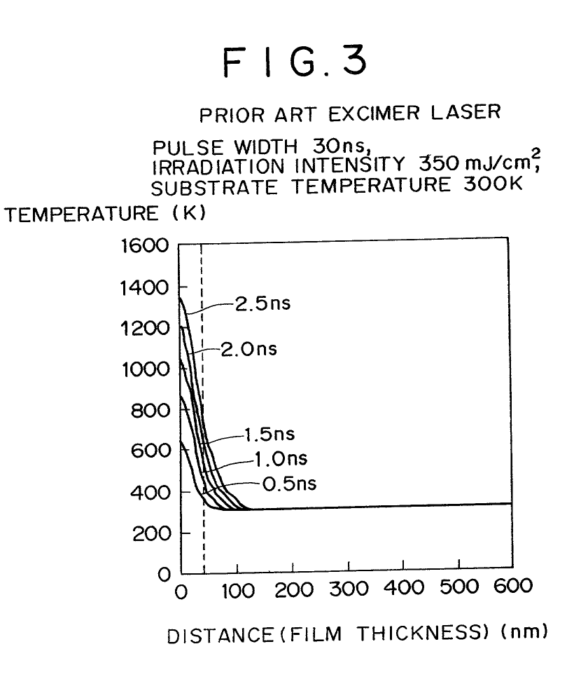

FIG. 3 is a graph showing the temperature distribution in a semiconductor thin film which appears upon irradiation with the conventional excimer laser by simulation. The ordinate and abscissa in FIG. 3 represent temperature in K and distance (film thickness) in nm, respectively. The temperature distribution due to irradiation with the conventional excimer laser has been calculated assuming an intensity of 350 mJ/cm², a pulse width of 30 ns, and a substrate temperature of 300 K. The five curves in FIG. 3 respectively denote elapsed time (0.5 ns, 1.0 ns, 1.5 ns, 2.0 ns, 2.5 ns) after laser irradiation. This graph was obtained by simulation based on the data available from Lambda Co., Ltd. It is assumed that the semiconductor thin film has a thickness of 40 nm. It is noted that the temperature distribution in the thickness direction has a steeper slope as the thin film increases in thickness. This suggests that irradiation with an excimer laser beam with a small pulse width merely heats the vicinity of the surface of the thin film in a short time without appreciable temperature rise inside the thin film and at the interface between the thin film and the substrate, with the result that degassing takes place only in the surface and but does not take place inside the thin film.

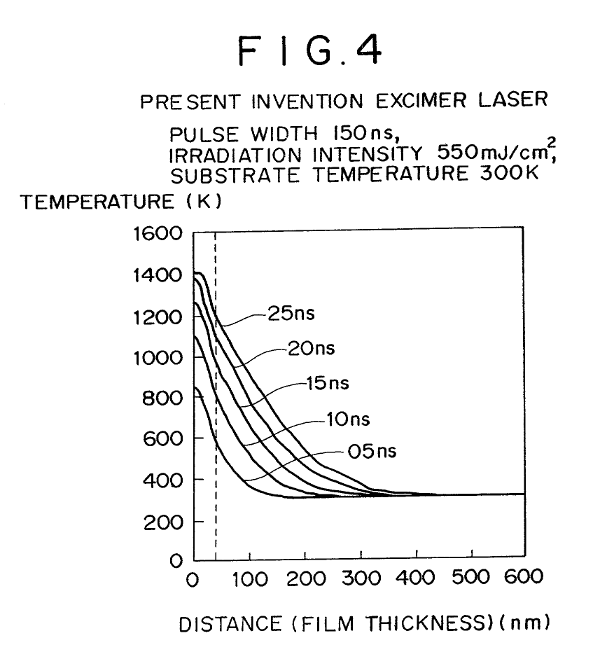

FIG. 4 is a contrasting diagram showing the temperature distribution in a semiconductor thin film which takes place upon irradiation with an excimer laser beam having a pulse width of 60 ns or more according to the present invention. This diagram is based on the results of simulation. The ordinate and abscissa in FIG. 4 represent temperature in K and distance (film thickness) in nm, respectively. Simulation was performed assuming an intensity of 550 mJ/cm², a pulse width of 150 ns, and a substrate temperature of 300 K. The five curves in FIG. 4 respectively denote elapsed time (5 ns, 10 ns, 15 ns, 20 ns, 25 ns) after laser irradiation. The curve of temperature distribution for an elapsed time of 10 ns indicates that the surface temperature is about 1100° C., which is slightly lower than the crystallizing temperature, whereas the temperature within the thin film gradually decreases from 1100° C. to 800° C. in going in the thickness direction. It also indicates that the temperature is about 800° C. at the interface (40 nm deep from the surface of the thin film) between the semiconductor thin film and the substrate. This temperature distribution helps remove hydrogen effectively.

The excimer laser of the present invention, which has a larger pulse width than the conventional excimer laser, adequately raises the temperature within the thin film without excessively raising the temperature in the surface of the thin film or while keeping the temperature in the surface of the thin film below the melting temperature or recrystallizing temperature of the material of the thin film. This temperature distribution permits uniform degassing in all regions across the thickness of the thin film.

### SECOND EMBODIMENT

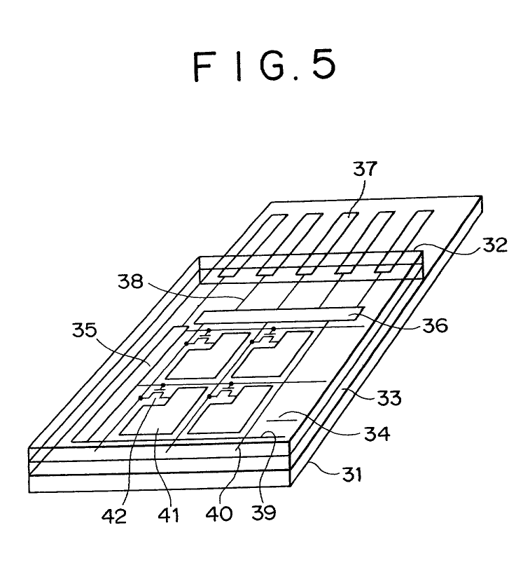

This embodiment demonstrates, with reference to FIG. 5, a display unit of active matrix type as a semiconductor device with thin film transistors produced according to the present invention. In this embodiment, the excimer laser having a pulse width of 60 ns or more is used for degassing (hydrogen removal) to form a thin film as a channel. The display unit shown in FIG. 5 consists of a pair of insulating substrates 31 and 32 and an electro-optic substance 33 such as liquid crystal held between them. The lower insulating substrate 31 has pixel array portions 34 and driving circuit portions formed by integration thereon. Each driving circuit portion consists of vertical scanner 35 and horizontal scanner 36. There are terminals 37 for external connection on the top of the periphery of the insulating substrate 31. The terminals 37 are connected to the vertical scanner 35 and horizontal scanner 36 through the wiring 38. Each pixel array portion 34 consists of gate wiring 39 in row and signal wiring 40 in column. At the intersect of the two wirings are formed a pixel electrode 41 and a thin-film transistor 42 to drive it. The thin-film transistor 42 has a gate electrode, which is connected to the corresponding gate wiring 39, a drain region, which is connected to the corresponding pixel electrode 41, and a source region, which is connected to the corresponding signal wiring 40. The gate wiring 39 is connected to the vertical scanner 35, and the signal wire 40 is connected to the horizontal scanner 36. The thin film transistor 42 to drive the pixel electrode 41 and the thin film transistors contained in the vertical scanner 35 and horizontal scanner 36 are those which have the thin film channel portion which has been degassed by irradiation with an excimer laser beam having a pulse width of 60 ns or more according to the process used in the first embodiment. Incidentally, the insulation substrate 31 may contain, in addition to the vertical and horizontal scanners, video drivers and timing generators.

### THIRD EMBODIMENT

This embodiment demonstrates the process for producing a thin film in which the steps of the first embodiment further include a second degassing step for removal of volatile gas.

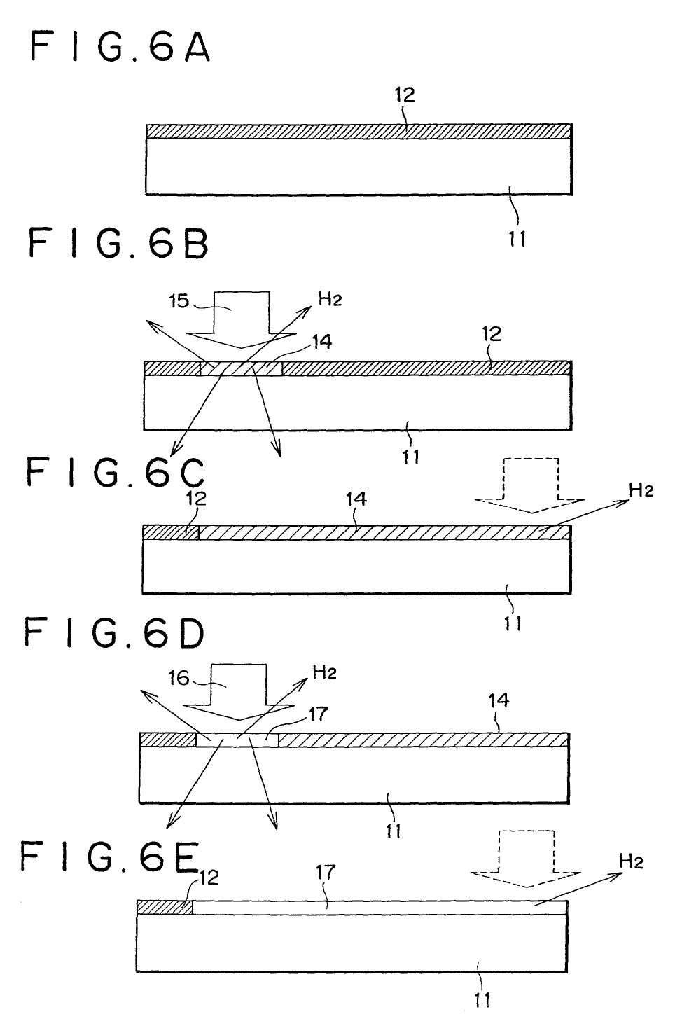

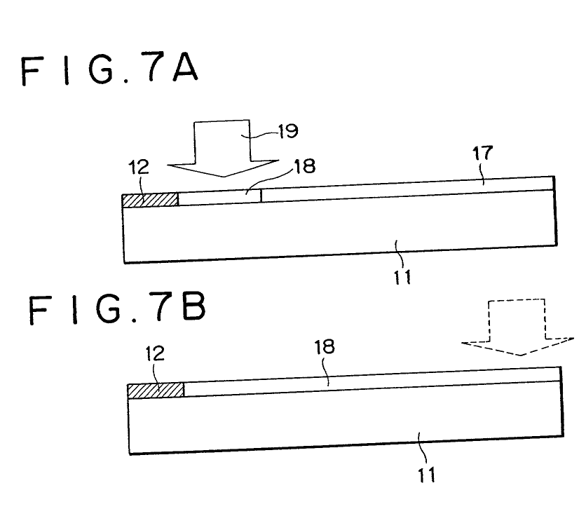

According to this embodiment, the process for producing a thin film consists of steps shown in FIGS. 6A to 6E and FIGS. 7A and 7B. As in the first embodiment, the process of this embodiment starts with forming an amorphous semiconductor thin film 12 by plasma-enhanced CVD on an insulating substrate 11 of glass, quartz, sapphire, or the like, as shown in FIG. 6A. The glass substrate includes glass plate having low heat resistance. The resulting amorphous semiconductor thin film 12 may contain more than 10 atom % hydrogen depending on the CVD condition. It is approximately 50 nm thick.

The insulating substrate 11 having the amorphous semiconductor thin film 12 formed thereon is mounted on the laser degassing apparatus mentioned above. It is irradiated with a first excimer laser beam 15 so that an irradiated region 14 is formed in part of the amorphous semiconductor thin film 12, as shown in FIG. 6B. The first laser beam 15 should be one which has a pulse width of 60 ns or more, preferably from 60 ns to 300 ns, more preferably from 100 ns to 250 ns, and most desirably from 120 ns to 230 ns. In addition, the excimer laser beam should have an energy intensity of 200 to 250 mJ/cm² so that it does not cause the thin film to crystallize nor explode. Irradiation may be performed once or several times (from twice to about 20 times), each with an energy intensity of 200 to 250 mJ/cm². Irradiation with an excimer laser beam having a pulse width of 60 ns or more removes volatile gas such as hydrogen from the amorphous semiconductor thin film 12. The amorphous semiconductor thin film 12 may initially contain 10 atom % hydrogen or more, but the hydrogen content in the irradiated region 14 decreases as the result of irradiation. In the first stage of laser irradiation, the hydrogen content decreases 8 atom % or below.

The area of laser irradiation is expanded as shown in FIG. 6C to such an extent that the irradiated region 14 occupies a large portion of the amorphous semiconductor thin film 12 on the insulating substrate 11. This is accomplished by moving the stage in the chamber of the degassing apparatus in such a way that one edge of the rectangular cross section of the laser beam overlaps with one edge of the rectangular cross section of the next laser beam. Irradiation may be carried out intermittently in sequence. Such irradiation may be carried out not only in such area-sequence but also in line-sequence. It is possible to scan the laser beam instead of moving the stage, or it is possible to move both the stage and the laser beam. The thin film in the irradiated region 14 contains hydrogen at a reduced level.

The first degassing step is followed by the second degassing step by irradiation with a second excimer laser beam. That is, the irradiated region 14 which has been irradiated with a first excimer laser beam 15 is irradiated again with a second laser beam 16, as shown in FIG. 6D. The second laser beam 17 should have a pulse width of 60 ns or more, preferably from 60 ns to 300 ns, more preferably from 100 ns to 250 ns, and most desirably from 120 ns to 230 ns. The second excimer laser beam has a higher energy intensity than the first excimer laser. For example, it has an energy intensity of 330 to 350 mJ/cm². Irradiation may be performed once or several times (from twice to about 40 times), each with an energy intensity of 300 to 350 mJ/cm². Irradiation with an excimer laser having a pulse width of 60 ns or more removes more hydrogen from the amorphous semiconductor thin film 12. The amorphous semiconductor thin film 12 may initially contain 10 atom % hydrogen or more, but the hydrogen content in the irradiated region 17 decreases as the result of irradiation with the second laser beam 16. The energy intensity of the second laser beam 16 may be equal to or different from that of the first laser beam 15.

Irradiation with the second excimer laser beam is expanded to such an extent that the irradiated region 17 occupies a large portion of the amorphous semiconductor thin film 12 on the insulating substrate 11, as shown in FIG. 6E. This is accomplished by moving the stage in the chamber of the degassing apparatus in such a way that one edge of the rectangular cross section of the laser beam overlaps with one edge of the rectangular cross section of the next laser beam. Irradiation may be carried out intermittently in sequence. Such irradiation may be carried out not only in such area-sequence but also in line-sequence. It is possible to scan the laser beam instead of moving the stage, or it is possible to move both the stage and the laser beam. The thin film in the irradiated region 17 contains hydrogen at a reduced level.

The process shown in FIG. 6 is carried out in such a way that the substrate is entirely irradiated with the first excimer laser beam and then the substrate is entirely irradiated again with the second excimer laser beam. However, the process may be changed such that a small portion of the substrate is sequentially irradiated with the first excimer laser beam and the second excimer laser beam and this step is repeated to irradiate the entire surface of the substrate.

Then the irradiated region 17 of the amorphous semiconductor thin film 12 is annealed for recrystallization by irradiation with an excimer laser beam 19, as shown in FIG. 7A. The excimer laser beam used in this step has an intensity (e.g., 500 mJ/cm²) higher than the crystallization energy of the material of the amorphous semiconductor thin film 12. Irradiation is carried out once or several times. As the result of irradiation, the amorphous semiconductor thin film 12 undergoes recrystallization and turns into the recrystallized region 18 of polycrystalline semiconductor thin film composed of large crystal grains.

The step of forming the recrystallized region 18 is repeated by moving the stage in the chamber in such a way that one edge of the rectangular cross section of the laser beam overlaps with one edge of the rectangular cross section of the next laser beam, as shown in FIG. 7B. Irradiation may be carried out intermittently in sequence. Such irradiation may be carried out not only in such area-sequence but also in line-sequence. It is possible to scan the laser beam instead of moving the stage, or it is possible to move both the stage and the laser beam. The step of forming the recrystallized region 18 proceeds without the semiconductor thin film 12 exploding because of its reduced hydrogen content after conversion into the irradiated region 17. Irradiation with a laser beam in multiple stages uniformly reduces the content of volatile gas such as hydrogen. The amorphous semiconductor thin film 12 may initially contain 10 atom % hydrogen or more, but the hydrogen content in the irradiated region 18 decreases as the result of repeated irradiation with a laser beam.

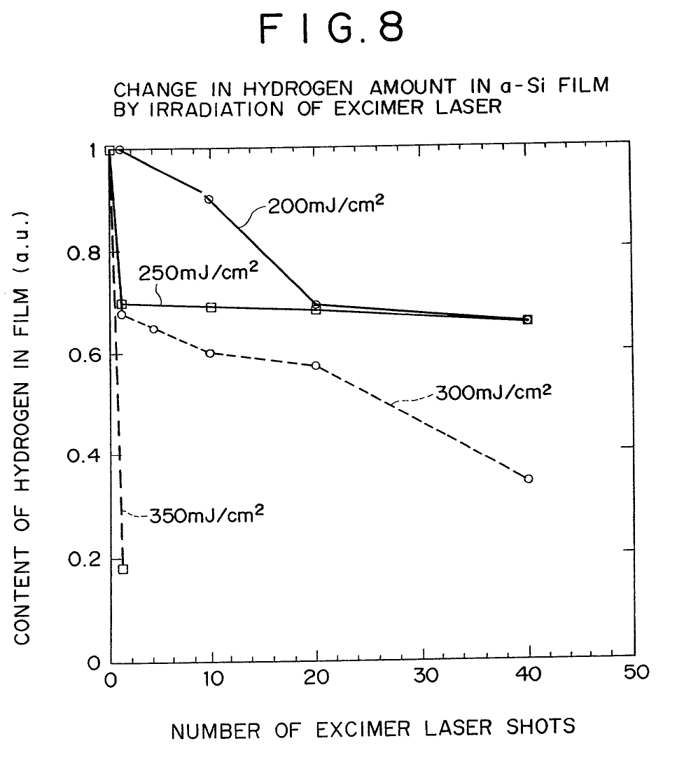

Degassing by repeated irradiation with a laser beam reduces the hydrogen content in the thin film differently depending on the energy density and the number of shots, as shown in FIG. 8. FIG. 8 was obtained from experiments with an amorphous silicon thin film about 40 nm in thickness which was irradiated with XeCl excimer laser (wavelength 308 nm) having a pulse width of 150 to 200 ns. The ordinate represents the hydrogen content in the thin film in arbitrary unit relative to the unity which is the hydrogen content measured immediately after the thin film had been formed on the insulating substrate by CVD. The abscissa represents the number of shots of XeCl excimer laser. It is apparent from the graph shown in FIG. 8 that the hydrogen content almost levels off at about 0.7 to 0.6 after 20 to 40 shots of irradiation with an excimer laser beam having an energy intensity of 200 to 250 mJ/cm². This means that the hydrogen content in the thin film decreases to 0.7 to 0.6 after the first laser irradiation in view of the fact that the first laser irradiation in this embodiment has an energy intensity of 200 to 250 mJ/cm². By contrast, one shot or a few shots of irradiation with excimer laser having an energy intensity higher than 300 mJ/cm², say 350 mJ/cm², greatly reduce the hydrogen content in the thin film, that is, from 1 (initial value) to about 0.2. This level is equal to that attained by annealing in an electric furnace. Reduction to such a low level makes further laser irradiation unnecessary. In this embodiment, the second laser irradiation with an energy intensity of 300 to 350 mJ/cm² accomplishes degassing with certainty.

Although the second laser irradiation is sufficient for degassing, the multi-stage laser irradiation is more effective in producing semiconductor thin film for stable devices and in making the hydrogen content uniform in the thin film.

### FOURTH EMBODIMENT

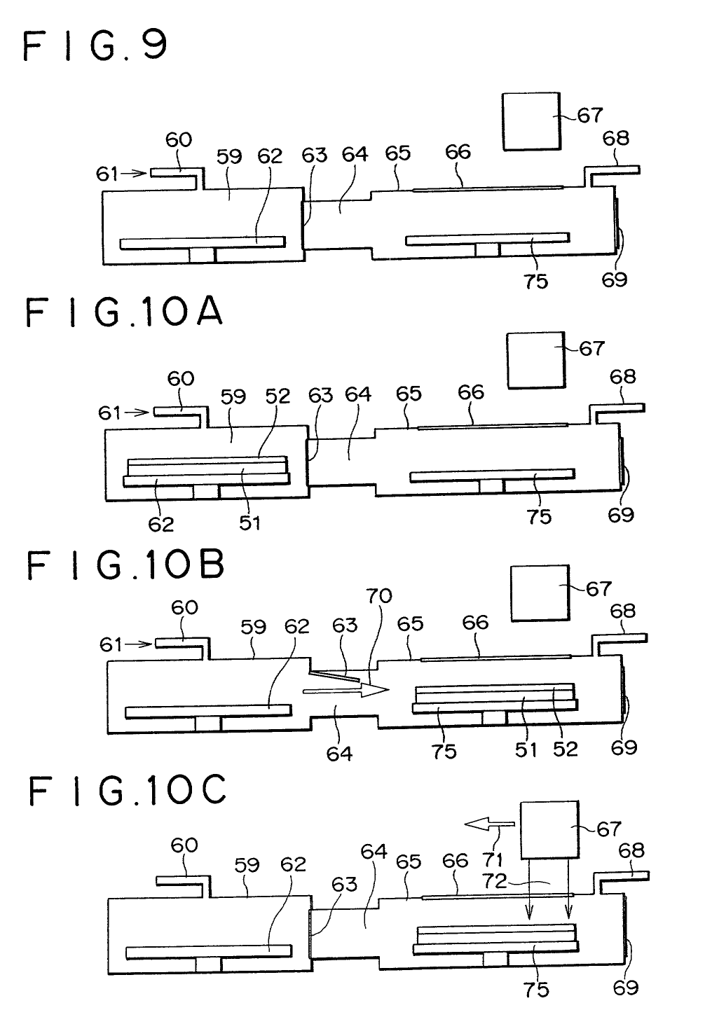

This embodiment demonstrates the process and apparatus for producing a semiconductor thin film with reference to FIGS. 9 to 11.

The apparatus for producing a semiconductor thin film is shown in FIG. 9, which is a schematic sectional view. It is composed mainly of a CVD chamber 59 and a laser irradiating chamber 65, which are joined together through a transfer chamber 64.

The CVD chamber 59 is designed to form a thin film by CVD on a substrate placed on a sample holder 62. It has at its top a gas inlet 60 for introduction of a reactant gas 61. The transfer chamber 64 permits the treated substrate to be transferred from the CVD chamber 59 to the laser irradiating chamber 65 without exposure to the atmosphere. There is a gate 63 between the CVD chamber 59 and the transfer chamber 64. The gate 63 is closed while CVD is being carried out to form a thin film, so that no gas flows from the CVD chamber 59 to the transfer chamber 64. The laser irradiating chamber 65 is designed to degas the thin film by irradiation with a laser beam and to anneal the thin film for recrystallization. It has a sample holder 75 on which is placed the substrate which has been transferred through the transfer chamber 64. On the top of the laser irradiating chamber 65 is a quartz window 66 that transmits a laser beam emitted from the excimer laser 67. The laser beam strikes the substrate placed in the laser irradiating chamber 65. Also on the top of the laser irradiating chamber 65 is a gas inlet 68 through which nitrogen is introduced into the laser irradiating chamber 65. The side wall of the laser irradiating chamber 65 is provided with an exit 69 through which the irradiated substrate is discharged.

The excimer laser 67 arranged above the laser irradiating chamber 65 emits a laser beam having a pulse width of 60 ns or more. In this embodiment, it works for both degassing and recrystallization by annealing as it changes in energy density. The excimer laser 67 is movable in the horizontal direction relative to the substrate placed on the sample holder 75.

The apparatus for producing semiconductor thin film, which is shown in FIG. 9, is used for degassing and crystallization in the way explained below with reference to FIGS. 10 and 11.

First, a substrate 51 is placed on the sample holder 62 in the CVD chamber 59, as shown in FIG. 10A. With the gate 63 closed, CVD starts to form an amorphous silicon (a-Si) film 52 on the substrate 51 by introduction of silane and hydrogen through the gas inlet 60 with concomitant plasma discharge. In the case of plasma-enhanced CVD like this, the resulting amorphous silicon film 52 inevitably contains hydrogen.

With plasma discharge and gas supply suspended, the CVD chamber 59 is evacuated. Then, the transfer chamber 64 and the laser irradiating chamber 65 are also evacuated. With the gate 63 opened, the substrate 51, which has been processed in the CVD chamber 59 to form a thin film thereon, is transferred in the direction of arrow 70 as shown in FIG. 10B. The substrate 51 passes through the transfer chamber 64 and reaches the laser irradiating chamber 65. The substrate 51 is placed on the sample holder 75 in the laser irradiating chamber 65. The gate 63 between the CVD chamber 59 and the transfer chamber 64 is closed after the substrate 51 passes through. During transfer from the CVD chamber 59 to the laser irradiating chamber 65, the substrate 51 is not exposed to the atmosphere. The above-mentioned procedure is completed within a short time without contamination.

The substrate 51, which has been placed on the sample holder 75 in the laser irradiating chamber 65, is irradiated with a laser beam 72 for degassing (removal of hydrogen from the amorphous silicon film 52 formed thereon), as shown in FIG. 10C. The laser beam 72 emitted from the excimer laser 67 has a pulse width of 60 ns or more and an energy density of about 300 mJ/cm². This energy density is a little insufficient to melt and crystallize the amorphous silicon film 52. The laser beam 72 emitted from the excimer laser 67 does not cover the entire surface of the amorphous silicon film 52 on the substrate 51. Therefore, the excimer laser 67 has to move parallel to the substrate 51 in the direction of arrow 71 as shown in FIG. 10C. In this way the excimer laser 67 scans the entire surface of the amorphous silicon film 52 for degassing. Alternatively, the apparatus may be constructed such that the sample holder 75 is moved horizontally by means of an X-Y stage, with the excimer laser 67 held stationery. In this case the laser irradiating chamber 65 should be twice in size as large as that of the substrate 51 to move about therein. Another possible arrangement is to make movable both the excimer laser 67 and the sample holder 75. Irradiation with the laser beam 72 instantaneously reduces the hydrogen content, say 2 atom % or below, in the amorphous silicon film 52. This degassing is as effective as that achieved by annealing in an electric furnace.

The degassing step is followed by the step of crystallizing the amorphous silicon film 52 by irradiation with the laser beam 73 emitted from the excimer laser 67. The laser beam 73 has an energy density of about 500 mJ/cm². Irradiation with the laser beam 73 does not explode the thin film which has been irradiated with the laser beam 72 for degassing. Irradiation with the laser beam 73 may be accomplished by moving the excimer laser 67 in the direction of arrow 71 as shown in FIG. 11A. In this way it is possible to scan the laser beam 73 for crystallization over the entire surface of the amorphous silicon film 52 on the substrate 51. Alternatively, the apparatus may be constructed such that the sample holder 75 is moved horizontally by means of an X-Y stage, with the excimer laser 67 held stationery. Another possible arrangement is to make movable both the laser beam 73 of the excimer laser 67 and the sample holder 75.

The procedure is completed by discharging the substrate 51, which has undergone degassing and crystallization, through the exit 69 formed on the side wall of the laser irradiating chamber 65, as shown in FIG. 11B.

In this embodiment, the amorphous silicon film 52 on the substrate 51 undergoes both degassing and crystallization by irradiation with a laser beam emitted from the same excimer laser 67. The procedure in this embodiment has an advantage over the conventional one which takes about two hours for transfer from the CVD apparatus to the laser annealing apparatus with inevitable exposure to the atmosphere because degassing is carried out in an electric furnace. By contrast, all the steps (CVD, degassing, and crystallization) in this embodiment are carried out by using the same apparatus for producing semiconductor thin film. This leads to high productivity. In addition, the complete degassing that precedes crystallization prevents the amorphous silicon film 52 from exploding. This contributes to high-quality crystalline semiconductor thin film.

### FIFTH EMBODIMENT

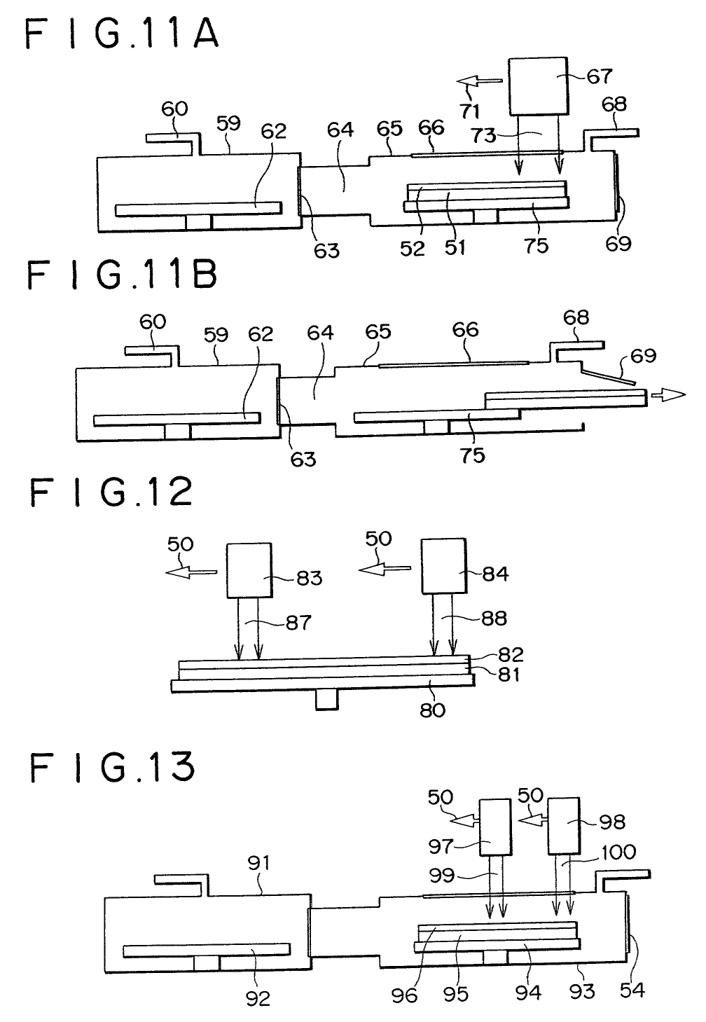

This embodiment demonstrates an apparatus for producing a semiconductor thin film, as shown in FIG. 12. The apparatus consists of a sample holder 80 and a pair of excimer laser emitters 83 and 84. On the sample holder 80 is placed a substrate 81 on which is formed an amorphous silicon film 82. The excimer laser emitters 83 and 84 face the amorphous silicon film 82. They are movable in the direction of arrow 50. The first excimer laser emitter 83 emits the laser beam 87 which strikes the amorphous silicon film 82. The laser beam 87 has a pulse width of 60 ns or more, which is suitable for degassing (or removal of hydrogen) and has an energy density of 300 to 350 mJ/cm². The second excimer laser emitter 83 emits the laser beam 88 after the first laser emitter 83 has emitted the laser beam 87. The laser beam 88 has an energy density of 500 to 600 mJ/cm².

As the paired excimer laser emitters 83 and 84 move in the direction of arrow 50, the amorphous silicon film 82 on the substrate 81 successively undergoes degassing and recrystallization. At the time of recrystallization, the amorphous silicon film 82 is exempt from explosion because it has already been degassed. The apparatus shown in FIG. 12 is constructed such that the paired excimer laser emitters 83 and 84 move in the direction of arrow 50. This construction may be modified such that the substrate 51 is moved or the excimer laser emitters 83 and 84 and the substrate 51 move relative to each other.

### SIXTH EMBODIMENT

This embodiment demonstrates an apparatus for producing semiconductor thin film which is combined with a CVD chamber, as shown in FIG. 13. The apparatus consists of a CVD chamber 91 and a laser irradiating chamber 93, which are joined together through a transfer chamber. The chambers are constructed in the same way shown in FIG. 9.

The CVD chamber 91 constitutes a space in which a reactant gas introduced therein forms by CVD a thin film on a substrate placed on the sample holder 92. The laser irradiating chamber 93 constitutes a space in which the thin film is irradiated with a laser beam for degassing and annealing for recrystallization. It has the sample holder 94 on which is placed the substrate 95 transferred from the transfer chamber. In the upper wall of the laser irradiating chamber 93 is a quartz window which transmits the laser beam. The laser beams emitted from the paired excimer laser emitters 97 and 98 pass through this quartz window and strike the thin film 96 on the substrate placed in the laser irradiating chamber 93.

The first excimer laser emitter 97 emits the laser beam 99 which has a pulse width of 60 ns or more. This laser beam is intended for degassing of the thin film 96 formed on the substrate. The second excimer laser emitter 98 emits the laser beam 100 which is intended for annealing for recrystallization of the thin film 96 on the substrate. The paired excimer laser emitters 97 and 98 are movable in the direction of arrow 50. As the paired excimer laser emitters 97 and 98 move in the direction of arrow 50, the amorphous silicon film 96 on the substrate 95 successively undergoes degassing and recrystallization. At the time of recrystallization, the amorphous silicon film 96 is exempt from explosion because it has already been degassed. The apparatus shown in FIG. 13 is constructed such that the paired excimer laser emitters 97 and 98 move in the direction of arrow 50. This construction may be modified such that the substrate 95 is moved or the excimer laser emitters 97 and 98 and the substrate 95 move relative to each other.

### SEVENTH EMBODIMENT

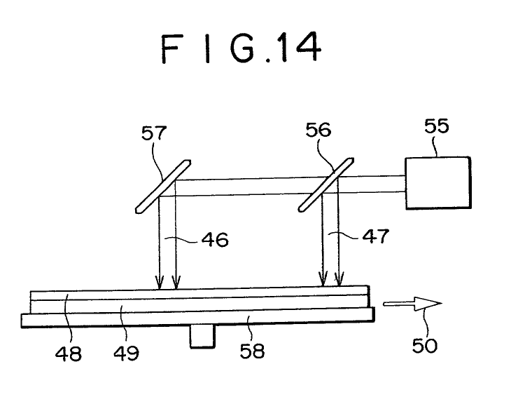

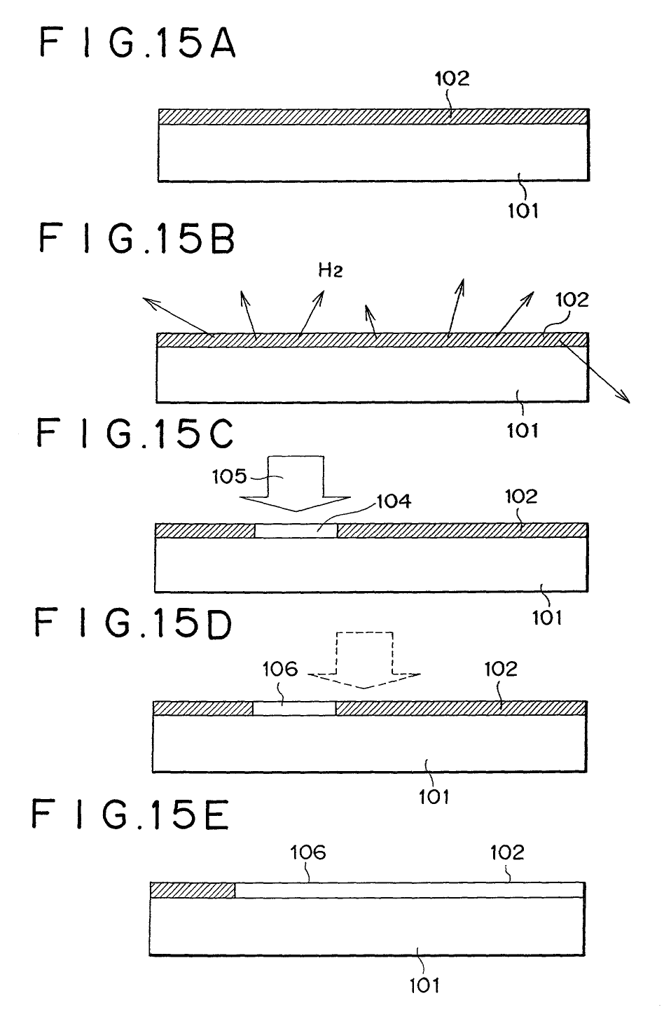

This embodiment demonstrates an apparatus for producing a semiconductor thin film which is characterized in that a laser beam emitted from a laser emitter is divided by a beam splitter into two laser beams, one laser beam striking the semiconductor thin film for degassing and the other laser beam striking the semiconductor thin film for recrystallization. The apparatus is constructed as shown in FIG. 14. It has one laser emitter 55 which emits a laser beam having a pulse width of 60 ns or more. The laser beam is split by the beam splitter 56 placed in the passage of the laser beam. One laser beam 46 split by the beam splitter 56 directly strikes the semiconductor thin film 48 on the substrate 49. This laser beam 46 serves for degassing. The other laser beam which has passed through the beam splitter 56 is reflected by the mirror 57, and the reflected laser beam 47 strikes the semiconductor thin film 48 on the substrate 49 for crystallization. The apparatus shown in FIG. 14 has the sample holder 58 on which is fixed the substrate 49. The sample holder 58 moves in the direction of arrow 50 so that the almost entire surface of the semiconductor thin film 48 successively undergoes degassing by the laser beam 46 and crystallization by the laser beam 47.

The apparatus in this embodiment has an optical system arranged such that the laser beam 46 having a low energy density for degassing is reflected by the beam splitter 56 and the laser beam 47 having a high energy density for crystallization passes through the beam splitter 56. The optical system may be modified such that the order of the laser beams is reversed. The apparatus in this embodiment works such that the sample holder 58 moves while degassing and crystallization proceed. This construction may be modified such that the laser unit moves or the laser unit and the holder move relative to each other. The optical system in this embodiment splits the laser beam into two; however, the optical system may be modified such that the laser beam is split into three or more and the split laser beams are apart from one another.

### EIGHTH EMBODIMENT

This embodiment demonstrates the procedure for excimer laser irradiation to cause the semiconductor thin film to undergo degassing and crystallization simultaneously.

This embodiment differs from the foregoing ones in that the laser unit has a means (homogenizer) to make the laser intensity uniform across the laser beam, which upon emergence from the laser unit has an intensity variation conforming to Gaussian distribution. The laser beam which has passed through the homogenizer is then led to a slit so that the laser beam eventually has an intensity with square distribution. This embodiment employs two laser beams with uniform intensity which are arranged such that the primary beam adjoins the secondary beam or the trailing edge of the primary beam partly overlaps with the secondary beam. Irradiation with the secondary beam starts after irradiation with the primary beam has been suspended or before irradiation with the primary beam starts.

Irradiation should be carried out at an adequate laser beam intensity. That is, the secondary laser beam should have a lower intensity than the primary laser beam. (The secondary laser beam adjoins or overlaps with the trailing edge of the primary laser beam.) For example, the intensity of the secondary laser beam should be established such that irradiation with the secondary laser beam raises the film temperature to about 1100° C. which is lower than the silicon crystallization point. The primary laser beam is directed to the sample from above and the secondary laser beam is directed to the sample from below through the substrate. This arrangement may be reversed. Both the two laser beams may be directed to the sample from below.

Conventional laser annealing of an a-Si film on a substrate poses a problem that the part of the film in the trailing edge of the laser beam cools so rapidly that the crystallized silicon becomes amorphous again. In this embodiment, this problem is solved by continuing irradiating the trailing edge region (which has been annealed by irradiation of the primary laser beam) with the secondary laser beam (which has a lower intensity than the primary laser beam) even after irradiation of the primary laser beam has been suspended. In this way it is possible to prevent the trailing edge region from becoming amorphous again, thereby ensuring crystallization. It is further possible to minimize thermal discontinuity between a crystallized region and an uncrystallized region. The laser annealing mentioned above produces the effect of growing crystal grains, preventing crystal dislocations in the interface between a crystallized region and an uncrystallized region, and preventing intradefects in each crystal grain.

It is said that the conventional laser annealing method of repeating irradiation twice consecutively offers the advantage that the first irradiation warms the interface between the a-Si film and the substrate and the second irradiation performs crystallization in a stable manner. There still is the possibility that the end of the irradiated region becomes amorphous again on account of inevitable rapid cooling. By contrast, this embodiment produces the effect of protecting the end of the irradiated region from rapid cooling, preventing the crystallized region from becoming amorphous again, and making the crystallized regions compatible with one another. Another effect is that irradiation can be carried out by using two laser units installed above the substrate. This arrangement is easy to construct and is useful in the case of opaque substrate.

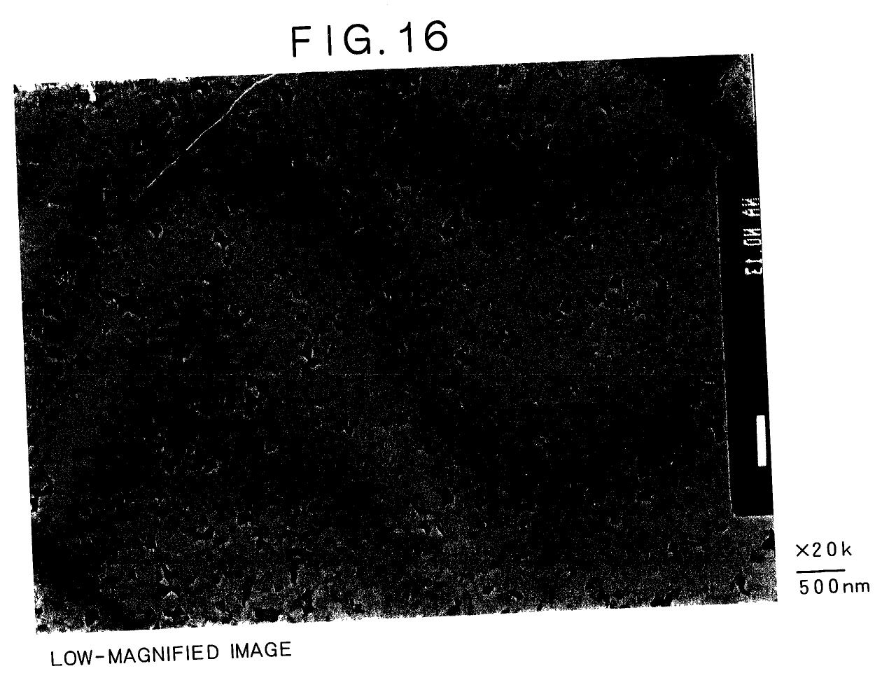

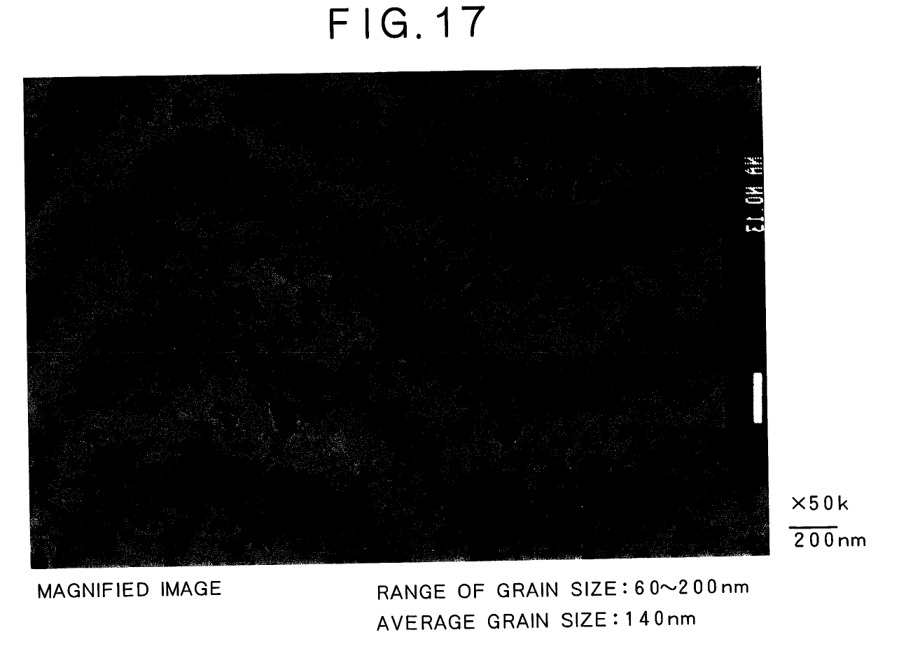

FIG. 16 is an electron micrograph (×20000) of a semiconductor thin film produced according to the present invention, and FIG. 17 is an enlarged image (×50000) thereof. The range of the grain size of the semiconductor thin film is 60 to 200 nm and the average grain size is 140 nm. As is clear from FIGS. 16 and 17, the semiconductor thin film thus produced is a polycrystalline film with uniform crystal grains.

### NINTH EMBODIMENT

This embodiment employs the primary and secondary laser beams which are arranged side by side or in such a way that the latter partly overlaps with the trailing edge of the former. The secondary laser beam starts irradiation after or before the primary laser beam has stopped irradiation. Irradiation is carried out in such a way that the trailing edge part of the thin film which has been melted by irradiation with the primary laser beam cools within a specific length of time as follows. In view of the fact that the maximum speed at which silicon becomes polycrystalline (not a-Si) is 20 m/s, the condition, specifically the intensity of the secondary laser beam is adjusted such that crystallization from the molten film on the substrate takes place within a length of time which is obtained by dividing the thickness of the thin film by the above-mentioned crystallization speed.

### TENTH EMBODIMENT

In this embodiment, the primary and secondary laser beams for laser-annealing the thin film on the substrate are arranged in such a way that the secondary laser beam adjoins or partly overlaps with the primary laser beam, with the secondary laser beam diverging or converging or being inclined against the primary laser beam.

According to the present invention, an amorphous semiconductor thin film on a substrate is irradiated with a laser beam having a comparatively large pulse width, say 60 ns or more. This laser beam removes hydrogen from the thin film, and hence the hydrogen content in the irradiated region decreases with certainty. Therefore, the ensuing irradiation with a laser beam having a high energy density does not pose any problems, such as explosion of this film, due to hydrogen. According to the present invention, the step for degassing by an excimer laser can be accomplished in a shorter time than the conventional step that employs an electric furnace. Thus the process of the present invention efficiently yields semiconductor thin film and semiconductor devices.

According to the present invention, the semiconductor thin film is irradiated with a laser beam having a comparatively large pulse, say 60 ns or more. Therefore, this laser beam achieves effective degassing without having to have a low energy density, say 60 to 150 mJ/cm². In addition, uniform degassing with good reproducibility can be achieved if irradiation is carried out by using two or more laser beams differing in energy intensity.

In addition, the present invention permits a semiconductor thin film to undergo degassing and crystallization simultaneously owing to its unique process consisting of deliberately incorporating a volatile gas (such as hydrogen) into a semiconductor thin film at the time of its formation and then irradiating the gas-containing thin film with an excimer laser having a long duration time per pulse. This process produces the effect of forming uniform nuclei invariably regardless of variation in film thickness and film quality and hence giving rise to a polycrystalline film with uniform crystal grains.

While the preferred embodiment of the present invention has been described using the specific terms, such description is for illustrative purposes only, and it is to be understood that changes and variations may be made without departing from the spirit or scope of the following claims.

What is claimed is:

1. A process for producing a thin film which comprises irradiating a raw thin film containing a volatile gas with an excimer laser beam having a pulse width of 60 ns or more, thereby removing said volatile gas from said raw thin film.

2. A process for producing a thin film as defined in claim 1, wherein said raw thin film contains at least 2 atom % volatile gas.

3. A process for producing a thin film as defined in claim 1, wherein irradiation with said excimer laser beam employs at least two kinds of laser beams.

4. A process for producing a thin film as defined in claim 1, wherein irradiation with at least said two excimer laser beams employs at least two kinds of laser beams differing in intensity.

5. A process for producing a thin film as defined in claim 4, wherein irradiation with two kinds of laser beams differing in intensity is achieved by repeating once or more irradiation with a laser beam having an intensity of 300 mJ/cm² or lower and irradiation with a laser beam having an intensity of 300 mJ/cm² or higher.

6. A process for producing a thin film as defined in claim 1, wherein said pulse width is from 60 ns to 300 ns.

7. A process for producing a thin film as defined in claim 6, wherein said pulse width is from 100 ns to 250 ns.

8. A process for producing a thin film as defined in claim 7, wherein said pulse width is from 120 ns to 230 ns.

9. A process for producing a thin film as defined in claim 1, wherein said excimer laser is one or more excimer lasers selected from Ar₂, Kr₂, Xe₂, F₂, Cl₂, KrF, KrCl, XeCl, XeF, XeBr, XeI, ArF, ArCl, HgCl, HgBr, HgI, HgCd, CdI, CdBr, ZnI, NaXe, XeTl, ArO, KrO, XeO, KrS, XeS, XeSe, Mg₂, and Hg₂.

10. A process for producing a thin film as defined in claim 1, wherein said raw thin film containing volatile gas is a semiconductor thin film.

11. A process for producing a thin film as defined in claim 10, wherein said semiconductor thin film contains either amorphous silicon film or polycrystalline silicon film in part of said film.

12. A process for producing a thin film as defined in claim 10, wherein said raw thin film is formed by any one or more of plasma CVD, low-pressure CVD, atmospheric CVD, catalytic CVD, photo CVD, and laser CVD.

13. A process for producing a thin film as defined in claim 10, wherein said raw thin film has a thickness in excess of 1 nm.

14. A process for producing a thin film as defined in claim 1, wherein said raw thin film contains as atoms constituting said volatile gas at least one species selected from hydrogen atom, helium atom, argon atom, neon atom, krypton atom, and xenon atom.

15. A process for producing a thin film as defined in claim 14, wherein said atoms constituting said volatile gas are contained in an amount of at least 2 atom %.

16. A process for producing a thin film which comprises irradiating a raw thin film containing a volatile gas with an excimer laser beam such that at least one region in the thickness direction of the raw thin film remains at a temperature lower than the recrystallizing temperature of the material of the raw thin film, thereby removing said volatile gas from said raw thin film.

17. A process for producing a thin film as defined in claim 16, wherein irradiation with said excimer laser beam is performed in such a way that the temperature in the vicinity of the surface of the raw thin film is lower than the recrystallizing temperature of the material of the raw thin film.

18. A process for producing a thin film as defined in claim 17, wherein the material of said raw thin film contains at least either amorphous silicon or polycrystalline silicon and the temperature in the vicinity of the raw thin film is in the range of 800° C. to 1100° C.

19. A process for producing a thin film as defined in claim 16, wherein the material of said raw thin film contains at least either amorphous silicon or polycrystalline silicon, the temperature in the vicinity of the surface of the raw thin film is higher than the recrystallizing temperature of the material of the raw thin film, and the temperature in the portion at a specific depth or more from the surface of the raw thin film is in the range of 800° C. to 1100° C.

20. A process for producing a thin film which comprises irradiating a thin film containing no less than 2 atom % of volatile gas with an excimer laser beam having a pulse width no shorter than 60 ns, thereby simultaneously removing said volatile gas from said thin film and crystallizing at least part of said thin film.

21. A process for producing a thin film as defined in claim 20, wherein said excimer laser beam has an intensity of irradiation energy higher than the threshold value of energy for said thin film to crystallize.

22. A process for producing a thin film as defined in claim 20, wherein said excimer laser is XeCl excimer laser.

23. A process for producing a thin film as defined in claim 22, wherein said excimer laser has an intensity of irradiation energy of 250 to 450 mJ/cm².

24. A process for producing a thin film as defined in claim 20, wherein said thin film containing a volatile gas is a semiconductor thin film.

25. A process for producing a thin film as defined in claim 24, wherein said semiconductor thin film contains at least partly amorphous silicon film.

26. A process for producing a thin film as defined in claim 24, wherein said thin film is one which has been formed by any one or more of plasma CVD, low-pressure CVD, atmospheric CVD, catalytic CVD, photo CVD, and laser CVD.

27. A process for producing a thin film as defined in claim 24, wherein said thin film has a thickness of 10 to 100 nm.

28. A process for producing a thin film as defined in claim 20, wherein said thin film contains at least one kind of atoms selected from hydrogen atoms, fluorine atoms, chlorine atoms, helium atoms, argon atoms, neon atoms, krypton atoms, and xenon atoms, of which said volatile gas is composed.

29. A process for producing a thin film as defined in claim 20, wherein said thin film is irradiated with said excimer laser beam more than once.

30. A process for producing a thin film as defined in claim 29, wherein said irradiation with excimer laser beam more than once is carried out with varied intensities of irradiation energy.

31. A process for producing a thin film as defined in claim 29, wherein said irradiation with excimer laser beam more than once is carried out such that the position of irradiation is shifted each time of irradiation.

32. A process for producing a thin film as defined in claim 30, wherein irradiation with said excimer laser beam is carried out more than once in such a way that the position of irradiation is shifted each time of irradiation so that the region of preceding irradiation partly overlaps with the region of succeeding irradiation.

33. A process for producing a thin film as defined in claim 30, wherein irradiation with said excimer laser beam is carried out more than once in such a way that the position of irradiation is shifted each time of irradiation so that the region of preceding irradiation adjoins the region of succeeding irradiation.

34. A process for producing a thin film as defined in claim 30, wherein at least part of the region for irradiation with said excimer laser is irradiated with spatially modulated excimer laser beam in such a way that the position of irradiation is shifted each time of irradiation.

35. A process for producing a thin film as defined in claim 34, wherein said spatial modulation is modulation of energy intensity.

36. A process for producing a thin film as defined in claim 34, wherein said modulation is accomplished in such a way that the intensity of irradiation energy decreases as the excimer laser beam advances.

37. A semiconductor thin film which contains less volatile gas than its raw thin film as the result of irradiation with an excimer laser beam having a pulse width of 60 ns or more.

38. A semiconductor thin film which is characterized in having the content of volatile gas therein reduced from 2 atom % or more and also having at least part thereof crystallized as the result of irradiation with excimer laser beams having a pulse width no shorter than 60 ns.

39. A semiconductor device which has a semiconductor thin film formed on a substrate, said semiconductor thin film containing less volatile gas than its raw thin film as the result of irradiation with an excimer laser beam having a pulse width of 60 ns or more.

40. A semiconductor device as defined in claim 39, wherein said substrate is a glass substrate.

41. A semiconductor device which comprises a semiconductor thin film on a substrate, said semiconductor thin film being one which has the content of volatile gas therein reduced from 2 atom % or more and also has at least part thereof crystallized as the result of irradiation with excimer laser beams having a pulse width no shorter than 60 ns.

42. A process for producing a semiconductor thin film which comprises forming a raw semiconductor thin film on a substrate, irradiating the raw semiconductor thin film with an excimer laser beam having a pulse width of 60 ns or more, thereby removing a volatile gas from said raw semiconductor thin film, and subsequently irradiating the degassed semiconductor thin film with an energy beam, thereby crystallizing said degassed semiconductor thin film.

43. A process for producing a semiconductor thin film as defined in claim 42, wherein said energy beam is an excimer laser beam.

44. A process for producing a semiconductor thin film as defined in claim 42, wherein irradiation with an excimer laser beam is carried out without the apparatus being opened to atmospheric air after a semiconductor thin film has been formed on a substrate.

45. A process for producing a semiconductor thin film as defined in claim 42, wherein irradiation with an excimer laser beam is carried out without the apparatus being opened to atmospheric air after a semiconductor thin film has been formed on a substrate, and crystallization of said semiconductor thin film is carried out without the apparatus being opened to atmospheric air after irradiation with said energy beam.

46. A process for producing a semiconductor thin film as defined in claim 42, wherein irradiation with said excimer laser is repeated once or more in such a way that the area of preceding irradiation partly overlaps with the area of succeeding irradiation.

47. A process for producing a semiconductor thin film which comprises forming on a substrate a semiconductor thin film containing no less than 2 atom% of volatile gas and irradiating said semiconductor thin film with an excimer laser beam having a pulse width no shorter than 60 ns, thereby simultaneously removing volatile gas from said semiconductor thin film and crystallizing at least part of said semiconductor thin film.

48. A process for producing a semiconductor thin film as defined in claim 47, wherein irradiation with an excimer laser beam is carried out, with the chamber kept shielded from the atmospheric air, after said semiconductor thin film has been formed on a substrate.

49. An apparatus for producing a semiconductor thin film which comprises a first treatment chamber in which a raw semiconductor thin film is formed on a substrate and a second treatment chamber adjacent to said first treatment chamber in which the substrate is irradiated with an excimer laser beam having a pulse width of 60 ns or more for removal of volatile gas from said raw semiconductor thin film formed on the substrate.

50. An apparatus for producing a semiconductor thin film as defined in claim 49, wherein said second treatment chamber is operated such that the semiconductor thin film is crystallized by irradiation with an energy beam.

51. An apparatus for producing a semiconductor thin film which comprises a laser emitter and a laser beam splitter, said laser beam splitter splits the laser beam emitted from the laser emitter such that one split laser beam strikes a semiconductor thin film for degassing and the other split laser beam strikes a semiconductor thin film for crystallization.

52. An apparatus for producing a semiconductor thin film which comprises a first treatment chamber in which a semiconductor thin film containing no less than 2 atom % of volatile gas is formed on a substrate and a second treatment chamber adjoining said first treatment chamber in which the substrate is irradiated with an excimer laser beam having a pulse width no shorter than 60 ns so that said semiconductor thin film formed on said substrate is freed of volatile gas and at the same time said semiconductor thin film is at least partly crystallized.
